(19) United States
(12) Patent Application Publication
(10) Pub. No.: US 2026/0162622 A1
(43) Pub. Date: Jun. 11, 2026

(54) GATE DRIVING CIRCUIT AND DISPLAY DEVICE INCLUDING A GATE DRIVER

(71) Applicant: LG Display Co., Ltd., Seoul (KR)

(72) Inventor: Tae Keun LEE, Paju-si (KR)

(73) Assignee: LG Display Co., Ltd., Seoul (KR)

(21) Appl. No.: 19/380,583

(22) Filed: Nov. 5, 2025

(30) Foreign Application Priority Data
Dec. 10, 2024 (KR) 10-2024-0182712

(51) Int. Cl. G09G 3/3266; G09G 3/36; G11C 19/28

(52) U.S. Cl. CPC G09G 3/3266; G11C 19/28; G09G 3/3677; G09G 2300/0819; G09G 2300/0852; G09G 2300/0861; G09G 2310/0286; G09G 2310/08; G09G 2340/0435

(57) ABSTRACT

A gate driving circuit and a display device including a gate driver are disclosed. The display device includes a display panel configured to display an image, and a gate driver including a shift register configured to generate signals for controlling transistors included in the display panel, wherein the shift register includes a first scan transistor turned on based on a voltage of a Q node to output a first-level signal through an output terminal, a second scan transistor turned on based on a voltage of a QB node to output a second-level signal through the output terminal, a third scan transistor turned on in response to a clock signal applied through a clock signal line to transmit a start signal applied through a start signal line to the Q node, and CMOS transistors configured to control the QB node based on the voltage of the Q node.

### CROSS-REFERENCE TO RELATED APPLICATION

This application claims the benefit of Korean Patent Application No. 10-2024-0182712, filed on Dec. 10, 2024, which is hereby incorporated by reference as if fully set forth herein.

### TECHNICAL FIELD

The present disclosure relates to a gate driving circuit(or a gate driver) and a display device including the gate driver.

### DESCRIPTION OF THE RELATED ART

As information technology develops, the market for display devices serving as connecting media between users and information, is growing. Accordingly, the use of display devices such as light emitting display (LED) devices, quantum dot display (QDD) devices, and liquid crystal display (LCD) devices is increasing.

The display devices described above include a display panel including subpixels, a driver that outputs a driving signal to drive the display panel, and a power supply that generates power to be supplied to the display panel or the driver.

The display devices described above can display images by allowing selected subpixels to transmit light or directly emit light when driving signals, such as a scan signal and a data signal, are supplied to the subpixels formed on the display panel.

### BRIEF SUMMARY

The present disclosure is directed to a gate driver and a display device including the same that, among others, substantially obviate one or more problems due to limitations and disadvantages of the related art.

The present disclosure provides a gate driver capable of reducing the number of transistors for controlling a QB node based on a CMOS transistor and solving a problem due to current leakage based on a shift register including an oxide semiconductor, and a display device including the same.

The present disclosure provides a gate driver capable of improving operation stability and operation reliability based on a shift register including at least one of an oxide semiconductor or a low-temperature polysilicon semiconductor, and a display device including the same.

Additional features and characteristics of the present disclosure will be set forth in part in the description which follows and in part will become apparent to those having ordinary skill in the art upon examination of the following or may be learned from practice of the present disclosure. The technical improvements and other advantages of the present disclosure may be realized and attained by the structure particularly pointed out in the written description and claims hereof as well as the appended drawings.

As embodied and broadly described herein, a display device includes a display panel configured to display an image, and a gate driver including a shift register configured to generate signals for controlling transistors included in the display panel, wherein the shift register includes a first scan transistor turned on based on a voltage of a Q node to output a first-level signal through an output terminal, a second scan transistor turned on based on a voltage of a QB node to output a second-level signal through the output terminal, a third scan transistor turned on in response to a clock signal applied through a clock signal line to transmit a start signal applied through a start signal line to the Q node, and CMOS transistors configured to control the QB node based on the voltage of the Q node.

The CMOS transistors may include a fourth scan transistor having a gate electrode connected to the Q node, a first electrode connected to a first voltage line through which a first voltage is transmitted, and a second electrode connected to the QB node, and a fifth scan transistor having a gate electrode connected to the Q node, a first electrode connected to a second voltage line through which a second voltage is transmitted, and a second electrode connected to the QB node.

The fourth scan transistor may be a p-type transistor based on a polysilicon semiconductor, and the fifth scan transistor may be an n-type transistor based on an oxide semiconductor.

The first scan transistor, the second scan transistor, and the third scan transistor may be n-type transistors based on an oxide semiconductor.

The display device may further include a first scan capacitor having a first electrode connected to a gate electrode of the first scan transistor and a second electrode connected to the output terminal, and a second scan capacitor having a first electrode connected to a gate electrode of the second scan transistor and a second electrode connected to the second voltage line.

The gate driver may include a scan driver configured to supply a scan signal to the display panel, and an emission control signal driver configured to supply an emission control signal to the display panel, and the shift register may be included in at least one of the scan driver and the emission control signal driver.

The gate driver may include a first scan driver configured to supply a first scan signal to the display panel, a second scan driver configured to supply a second scan signal to the display panel, a third scan driver configured to supply a third scan signal to the display panel, a fourth scan driver configured to supply a fourth scan signal to the display panel, and an emission control signal driver configured to supply an emission control signal to the display panel, and the shift register may be included in at least one of the first scan driver, the third scan driver, the fourth scan driver, and the emission control signal driver.

In another aspect of the present disclosure, a gate driving circuit includes a first scan transistor turned on based on a voltage of a Q node to output a first-level signal through an output terminal, a second scan transistor turned on based on a voltage of a QB node to output a second-level signal through the output terminal, a third scan transistor turned on in response to a clock signal applied through a clock signal line to transmit a start signal applied through a start signal line to the Q node, and CMOS transistors configured to control the QB node based on the voltage of the Q node.

The CMOS transistors may include a fourth scan transistor having a gate electrode connected to the Q node, a first electrode connected to a first voltage line through which a first voltage is transmitted, and a second electrode connected to the QB node, and a fifth scan transistor having a gate electrode connected to the Q node, a first electrode connected to a second voltage line through which a second voltage is transmitted, and a second electrode connected to the QB node.

The first scan transistor, the second scan transistor, the third scan transistor, and the fifth scan transistor may be n-type transistors based on an oxide semiconductor, and the fourth scan transistor may be a p-type transistor based on a polysilicon semiconductor.

It is to be understood that both the foregoing general description and the following detailed description of the present disclosure are exemplary and explanatory and are intended to provide further explanation of the present disclosure.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a block diagram schematically showing a display device;

FIG. 2 is a block diagram showing a configuration of a gate driver in the display device;

FIG. 3 is a cross-sectional view of a laminated structure of a display panel;

FIG. 4 is a diagram showing a circuit configuration of a subpixel according to the present disclosure;

FIG. 5 and FIG. 6 are diagrams showing driving waveforms of a display panel implemented based on the subpixel of FIG. 4 according to the present disclosure;

FIG. 7 is a diagram for describing driving characteristics of the display panel implemented based on the subpixel of FIG. 4;

FIG. 8 is a circuit configuration diagram of a shift register according to a first embodiment, FIG. 9 is a diagram showing driving waveforms of the shift register illustrated in FIG. 8, FIG. 10 and FIG. 11 show operation states of the shift register according to the driving waveforms shown in FIG. 9, and FIG. 12 shows output states of the shift register according to the first embodiment;

FIG. 13 is a circuit configuration diagram of a shift register according to a second embodiment; and

FIG. 14 is a circuit configuration diagram of a shift register according to a third embodiment.

### DETAILED DESCRIPTION

A display device according to the present disclosure may be implemented as a light emitting display (LED) device, a quantum dot display (QDD) device, a liquid crystal display (LCD) device, or the like. However, for convenience of description, a light emitting display device that directly emits light based on inorganic light-emitting diodes or organic light-emitting diodes is used as an example of the display device.

In addition, a light-emitting display device which will be described below may be implemented in the form of an n-type thin film transistor, a p-type thin film transistor, or a form in which both n-type and p-type thin film transistors exist together. A thin film transistor is a three-electrode element including a gate, a source, and a drain. The source is an electrode that supplies carriers to the transistor. In the thin film transistor, carriers start to flow from the source. The drain is an electrode through which carriers leave the thin film transistor. In other words, carriers flow from the source to the drain in the thin film transistor.

In the case of a p-type thin film transistor, holes serve as carriers, and thus a source voltage is higher than a drain voltage such that the holes can flow from the source to the drain. Since the holes flow from the source to the drain in the p-type thin film transistor, the current flows from the source to the drain. In contrast, in the case of an n-type thin film transistor, electrons serve as carriers, and thus the source voltage is lower than the drain voltage such that the electrons can flow from the source to the drain. Since the electrons flow from the source to the drain in the n-type thin film transistor, the current flows from the drain to the source. However, the source and drain of a thin film transistor can be changed depending on the applied voltage. To reflect this, in the following description, one of the source and drain is described as a first electrode, and the other of the source and drain is described as a second electrode.

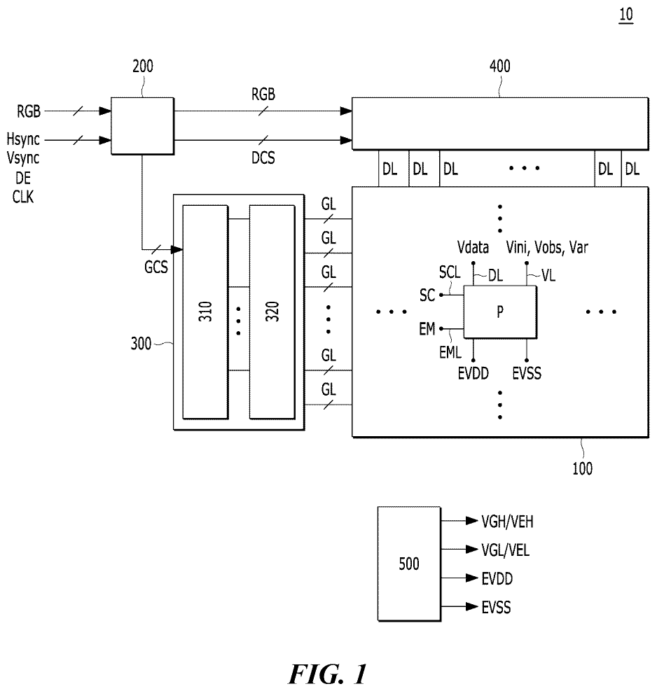

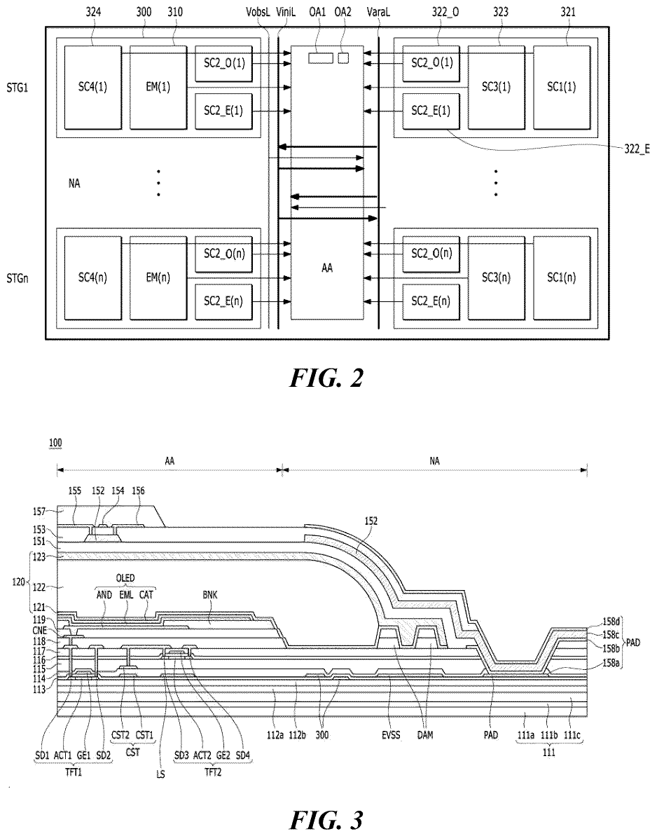

FIG. 1 is a block diagram schematically showing a display device. FIG. 2 is a block diagram showing a configuration of a gate driver in the display device.

As shown in FIG. 1, the display device 10 may include a display panel 100 including a plurality of subpixels P, a controller 200, a gate driver (gate driving circuit) 300 that supplies gate signals to the plurality of subpixels P, a data driver (data driving circuit) 400 that supplies data signals (or data voltages) to the plurality of subpixels P, and a power supply 500 that supplies power to the plurality of subpixels P.

The display panel 100 may include an active area (refer to AA in FIG. 2) in which the subpixels P are positioned, and a non-active area (refer to NA in FIG. 2) which is positioned to surround the active area AA and in which the gate driver 300 and the data driver 400 are disposed.

In the display panel 100, a plurality of gate lines GL and a plurality of data lines DL intersect each other, and the plurality of subpixels P may be connected to the gate lines GL and the data lines DL. Specifically, one subpixel P may receive a gate signal from the gate driver 300 through the gate line GL, receive a data voltage (data signal) from the data driver 400 through the data line DL, and receive a high-level voltage EVDD and a low-level voltage EVSS from the power supply 500.

The gate lines GL may transmit a scan signal SC and an emission control signal EM to the plurality of subpixels P, and the data lines DL may transmit a data voltage Vdata to the plurality of subpixels P. According to various embodiments, the gate lines GL may include a plurality of scan lines SCL for supplying the scan signal SC and a plurality of emission control lines EML for supplying the emission control signal EM. The plurality of subpixels P may receive voltages Vini, Var, and Vobs from a plurality of voltage lines VL. The voltages Vini, Var, and Vobs applied through the plurality of voltage lines VL will be described below.

Each of the plurality of subpixels P may include a subpixel driving circuit. The subpixel driving circuit may include a plurality of switching elements, driving elements, capacitors, etc. The switching elements and driving elements, etc., may be configured as thin film transistors. A switching transistor may be switched according to a scan signal SC supplied through a scan line SCL and an emission control signal EM supplied through an emission control line EML. A driving transistor may control the amount of current supplied to a light-emitting element OLED according to a data voltage Vdata (control the amount of emission).

The display panel 100 may be implemented as a non-transmissive display panel or a transmissive display panel. The transmissive display panel may be applied to a transparent display device in which an image is displayed on a screen and an actual object in the background is visible. The display panel 100 may also be implemented as a flexible display panel. The flexible display panel may use a plastic substrate. Each of the plurality of subpixels P may be divided into a red subpixel, a green subpixel, and a blue subpixel for color expression. Each of the plurality of subpixels P may further include a white subpixel.

Touch sensors may be disposed on the display panel 100. Touch input may be sensed using separate touch sensors or through the plurality of subpixels P. The touch sensors may be implemented as on-cell type or add-on type touch sensors disposed on the screen of the display panel or as in-cell type touch sensors built into the display panel 100.

The controller 200 may process image data RGB input from the outside to suit to the size and resolution of the display panel 100 and supply the same to the data driver 400. The controller 200 may generate a gate control signal GCS and a data control signal DCS using external synchronous signals, for example, a dot clock signal CLK, a data enable signal DE, a horizontal synchronization signal Hsync, and a vertical synchronization signal Vsync. The controller 200 may control the operation timing of the gate driver 300 by supplying the gate control signal GCS to the gate driver 300. The controller 200 may control the operation timing of the data driver 400 by supplying the data control signal DCS to the data driver 400. The controller 200 may synchronize the operation timing of the gate driver 300 with the operation timing of the data driver 400 using the gate control signal GCS and the data control signal DCS.

The controller 200 may be configured to be combined with various processors, such as a microprocessor, a mobile processor, and an application processor depending on the device mounted thereon. A host system located in front of the controller 200 may be any one of a television (TV) system, a set-top box, a navigation system, a personal computer (PC), a home theater system, a mobile device, a wearable device, or a vehicle system.

The controller 200 may control the operation timing of a display panel driver at a frame frequency of input frame frequency×i Hz (i being a positive integer greater than 0) by multiplying the input frame frequency by i. The input frame frequency may be 60 Hz in the NTSC (National Television Standards Committee) system and 50 Hz in the PAL (Phase-Alternating Line) system.

The controller 200 may drive the display panel 100 at various refresh rates. The controller 200 may drive the display panel 100 in a variable refresh rate (VRR) mode, that is, in such a manner that the display panel can be switched between a first refresh rate and a second refresh rate.

For example, the controller 200 may drive the display panel 100 at various refresh rates by simply changing the rate of a clock signal, configuring a synchronization signal such that a horizontal blank or a vertical blank is generated, or driving the gate driver 300 in a mask manner. The vertical blank can be defined as a period for matching the timing of input of a data signal and the timing of output (display) of an image on the display panel. The vertical blank can be repeated in one frame cycle, and various signals for the operation of the display device can be synchronized during the period.

The voltage level of the gate control signal GCS output from the controller 200 may be converted into an on voltage and an off voltage through a level shifter (not shown) and supplied to the gate driver 300. The level shifter may convert a low level voltage of the gate control signal GCS into a gate low voltage VGL and may convert a high level voltage of the gate control signal GCS into a gate high voltage VGH. The gate control signal GCS may include a start pulse signal and a shift clock signal.

The gate driver 300 may supply gate signals to the gate lines GL according to the gate control signal GCS supplied from the controller 200. The gate driver 300 may be disposed on one side or both sides of the display panel 100 in a gate-in-panel (GIP) structure.

The gate driver 300 may sequentially output gate signals to the plurality of gate lines GL under the control of the controller 200. The gate driver 300 may sequentially supply the gate signals to the gate lines GL by shifting the gate signals using a shift register.

The gate signals may include a scan signal SC and an emission control signal EM in an organic light-emitting display device. The scan signal SC may include a scan pulse that swings between the gate low voltage VGL and a gate high voltage VGH. The emission control signal EM may include an emission control signal pulse that swings between a gate on voltage VEL and a gate off voltage VEH. The scan pulse can select subpixels P of a line to which a data voltage Vdata will be written. The emission control signal EM can define an emission time of the subpixels P.

The gate driver 300 may include an emission control signal driver 310 and at least one scan driver 320. The emission control signal driver 310 may output an emission control signal pulse in response to a start pulse and a shift clock from the controller 200 and sequentially shift the emission control signal pulse according to the shift clock. The at least one scan driver 320 may output a scan pulse in response to a start pulse and a shift clock from the controller 200 and shift the scan pulse according to shift clock timing.

The data driver 400 may convert image data RGB into a data voltage Vdata according to a data control signal DCS supplied from the controller 200, and output the data voltage Vdata through a data line DL.

Although FIG. 1 illustrates that one data driver 400 is disposed one side of the display panel 100, the number and positions of data drivers 400 are not limited thereto. That is, the data driver 400 may be composed of a plurality of integrated circuits (ICs) which are disposed on one side of the display panel 100.

The power supply 500 may generate DC power to drive the subpixel array of the display panel 100 and the display panel driver using a DC-DC converter. The DC-DC converter may include a charge pump, a regulator, a buck converter, a boost converter, etc. The power supply 500 may receive a DC input voltage applied from the host system that is not shown and generate DC voltages such as gate voltages VGL, VEL, VGH, and VEH, the high-level voltage EVDD, and the low-level voltage EVSS.

As shown in FIG. 1 and FIG. 2, the gate driver 300 may include the emission control signal driver 310 and the scan driver 320. The scan driver 320 may include first to fourth scan drivers 321, 322, 323, and 324. In addition, the second scan driver 322 may include an odd-numbered second scan driver 322_O and an even-numbered second scan driver 322_E.

Shift registers constituting the gate driver 300 may be configured to be symmetrical on both sides of the active area AA. The shift register on one side may be included in the second scan driver 322_O and 322_E, the fourth scan driver 324, and the emission control signal driver 310, and the shift register on the other side may be included in the first scan driver 321, the second scan driver 322_O and 322_E, and the third scan driver 323. FIG. 2 illustrates an example in which the odd-numbered second scan driver 322_O and the even-numbered second scan driver 322_E are shared by an odd-numbered subpixel and an even-numbered subpixel. Therefore, the emission control signal driver 310 and the first to fourth scan drivers 321, 322, 323, and 324 may be disposed differently, and the present disclosure is not limited thereto.

Stages STG1 to STGn of the shift register may include first scan signal generators SC1(1) to SC1(n), second scan signal generators SC2_O(1) to SC2_O(n) and SC2_E(1) to SC2_E(n), third scan signal generators SC3(1) to SC3(n), fourth scan signal generators SC4(1) to SC4(n), and emission control signal generators EM(1) to EM(n), respectively.

The first scan signal generators SC1(1) to SC1(n) may output first scan signals through first scan lines SC1 of the display panel 100. The second scan signal generators SC2(1) to SC2(n) may output second scan signals through second scan lines SC2 of the display panel 100. The third scan signal generators SC3(1) to SC3(n) may output third scan signals through third scan lines SC3 of the display panel 100. The fourth scan signal generators SC4(1) to SC4(n) may output fourth scan signals through fourth scan lines SC4 of the display panel 100. The emission control signal generators EM(1) to EM(n) may output emission control signals through the emission control lines EM of the display panel 100.

A bias voltage line VobsL for transmitting a bias voltage Vobs, a first initialization voltage line ViniL for transmitting a first initialization voltage Vini, and a second initialization voltage line VaraL for transmitting a second initialization voltage Var may be disposed between the gate driver 300 and the active area AA.

In the drawing, the bias voltage line VobsL, the first initialization voltage line ViniL, and the second initialization voltage line VaraL are illustrated as being located on one of the left side or the right side of the active area AA, but the present disclosure is not limited thereto and they may be located on both sides, and even if located on one side, the location is not limited to the left or right.

Further, one or more optical areas OA1 and OA2 may be disposed in the active area AA. The optical areas OA1 and OA2 may be disposed to overlap one or more optoelectronic devices, such as imaging devices such as a camera (image sensor) and detection sensors such as a proximity sensor and an illuminance sensor.

The optical areas OA1 and OA2 may have a light-transmitting structure formed for the operation of the optoelectronic devices, and thus may have a transmittance of a certain level or higher. In other words, the number of pixels per unit area in the optical areas OA1 and OA2 may be smaller than the number of pixels per unit area in the general area other than the optical areas OA1 and OA2 in the active area AA. That is, the resolution of the optical areas OA1 and OA2 may be lower than the resolution of the general area in the active area AA.

The light-transmitting structure in the optical areas OA1 and OA2 may be formed by patterning a cathode in a region where no subpixels are disposed. At this time, the cathode to be patterned may be removed using a laser, or the cathode may be selectively formed and patterned using a material such as a cathode deposition prevention layer.

In addition, the light-transmitting structure in the optical areas OA1 and OA2 may be formed by separately forming the light-emitting element included in the subpixel and the subpixel driving circuit. In other words, the light-emitting element of the subpixel is positioned on the optical areas OA1 and OA2, and a plurality of transistors constituting the subpixel driving circuit is disposed on the periphery of the optical areas OA1 and OA2, and thus the light-emitting element and the subpixel driving circuit can be electrically connected through a transparent metal layer.

FIG. 3 is a cross-sectional view showing a laminated structure of the display panel.

As shown in FIG. 3, transistors TFT1 and TFT2 and a first capacitor CST for driving a light-emitting element OLED disposed in the active area AA may be disposed on a substrate 111 of the display panel 100. The transistors TFT1 and TFT2 may include either a switching thin film transistor or a driving transistor including a polycrystalline semiconductor material and an oxide thin film transistor including an oxide semiconductor material. In this case, the thin film transistor including a polycrystalline semiconductor material is referred to as a polycrystalline thin film transistor TFT1, and the thin film transistor including an oxide semiconductor material is referred to as an oxide thin film transistor TFT2. For example, the polycrystalline thin film transistor TFT1 may be connected to the light-emitting element OLED, and the oxide thin film transistor TFT2 may be connected to the first capacitor CST.

The substrate 111 may include a first substrate layer 111a, a second substrate layer 111b, and a third substrate layer 111c. The first substrate layer 111a and the third substrate layer 111c may be formed using organic films including polyimide, and the second substrate layer 111b located between the first substrate layer 111a and the third substrate layer 111c may be formed using an inorganic film including silicon oxide SiO₂.

A lower buffer layer 112a may be formed on the substrate 111. The lower buffer layer 112a may be formed by laminating multiple layers of silicon oxide SiO₂ to block moisture and the like that may penetrate from the outside. An auxiliary buffer layer 112b may be additionally formed on the lower buffer layer 112a to protect the element from moisture penetration.

The polycrystalline thin film transistor TFT1 may be formed on the substrate 111. The polycrystalline thin film transistor TFT1 may use a polycrystalline semiconductor for an active layer. The polycrystalline thin film transistor TFT1 may include a first active layer ACT1 including a channel through which electrons or holes move, a first gate electrode GE1, a first source electrode SD1, and a first drain electrode SD2. A first gate insulating layer 113 may be disposed between the first gate electrode GE1 and the first active layer ACT1, and the first gate insulating layer 113 may be formed by laminating an inorganic layer such as a silicon oxide (SiO₂) film or a silicon nitride (SiNx) film in a single or multiple layers.

The first active layer ACT1 may include a first channel region, a first source region disposed on one side of the first channel region, and a first drain region disposed on the other side of the first channel region. The first source region and the first drain region are conductive regions in which an intrinsic polycrystalline semiconductor material is doped with impurity ions of group 5 or group 3, such as phosphorus (P) or boron (B), at a predetermined concentration. The first channel region is a region in which the intrinsic state of a polycrystalline semiconductor material is maintained and can provide a path for electrons or holes to move.

According to one embodiment, the polycrystalline thin film transistor TFT1 may be implemented in a top gate structure in which the first gate electrode GE1 is positioned on the first active layer ACT1. Accordingly, a first electrode CST1 of the first capacitor CST and a light-shielding layer LS included in the oxide thin film transistor TFT2 can be formed of the same material as the first gate electrode GE1. The number of mask processes can be reduced by forming the first gate electrode GE1, the first electrode CST1, and the light-shielding layer LS through one mask process.

The first gate electrode GE1 may be formed of a metal material. For example, the first gate electrode GE1 may be a single layer or multiple layers formed of one of molybdenum (Mo), aluminum (Al), chromium (Cr), gold (Au), titanium (Ti), nickel (Ni), neodymium (Nd), and copper (Cu), or an alloy thereof, but the present disclosure is not limited thereto. A first interlayer insulating layer 114 may be disposed on the first gate electrode GE1. The first interlayer insulating layer 114 may be formed of silicon oxide (SiO₂), silicon nitride (SiNx), or the like.

The display panel 100 may further include an upper buffer layer 115, a second gate insulating layer 116, and a second interlayer insulating layer 117 sequentially laminated on the first interlayer insulating layer 114, and the polycrystalline thin film transistor TFT1 may include a first source electrode SD1 and a first drain electrode SD2 formed on the second interlayer insulating layer 117 and connected to the first source region and the first drain region, respectively.

The first source electrode SD1 and the first drain electrode SD2 may be a single layer or multiple layers formed of one of molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The upper buffer layer 115 may separate a second active layer ACT2 of the oxide thin film transistor TFT2 formed of an oxide semiconductor material from the first active layer ACT1 formed of a polycrystalline semiconductor material, and may provide a base for forming the second active layer ACT2.

The second gate insulating layer 116 may cover the second active layer ACT2 of the oxide thin film transistor TFT2. Since the second gate insulating layer 116 is formed on the second active layer ACT2 made of an oxide semiconductor material, the second gate insulating layer 116 may be formed using an inorganic film. For example, the second gate insulating layer 116 may be formed of silicon oxide (SiO₂), silicon nitride (SiNx), or the like.

A second gate electrode GE2 may be formed of a metal material. For example, the second gate electrode GE2 may be a single layer or multiple layers formed of one of molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The oxide thin film transistor TFT2 may be formed on the upper buffer layer 115. The oxide thin film transistor TFT2 may include the second active layer ACT2 formed of an oxide semiconductor material, the second gate electrode GE2 disposed on the second gate insulating layer 116, and a second source electrode SD3 and a second drain electrode SD4 disposed on the second interlayer insulating layer 117. The second active layer ACT2 may be formed of an oxide semiconductor material and may include an intrinsic second channel region that is not doped with impurities, and a second source region and a second drain region that are doped with impurities and thus are conductive.

The oxide thin film transistor TFT2 may further include the light-shielding layer LS positioned below the upper buffer layer 115 and overlapping the second active layer ACT2. The light-shielding layer LS may block light incident on the active layer ACT2 to secure the reliability of the oxide thin film transistor TFT2. The light-shielding layer LS is formed of the same material as the first gate electrode GE1 and may be formed on the upper surface of the first gate insulating layer 113. The light-shielding layer LS may also be electrically connected to the second gate electrode GE2 to form a dual gate (not shown in the figures).

The second source electrode SD3 and the second drain electrode SD4 may be simultaneously formed of the same material on the second interlayer insulating layer 117 together with the first source electrode SD1 and the first drain electrode SD2, thereby reducing the number of mask processes.

Meanwhile, the first capacitor CST may be formed by disposing a second electrode CST2 on the first interlayer insulating layer 114 to overlap the first electrode CST1. The second electrode CST2 may be a single layer or multiple layers made of, for example, one of molybdenum (Mo), aluminum (Al), chromium (Cr), gold (Au), titanium (Ti), nickel (Ni), neodymium (Nd), and copper (Cu), or an alloy thereof.

The first capacitor CST may store a data voltage applied through a data line DL for a predetermined period of time. The first capacitor CST may include two electrodes facing each other and a dielectric disposed therebetween. The first interlayer insulating layer 114 may be positioned between the first electrode CST1 and the second electrode CST2.

The first electrode CST1 or the second electrode CST2 of the first capacitors CST may be electrically connected to the second source electrode SD3 or the second drain electrode SD4 of the oxide thin film transistor TFT2. However, the present disclosure is not limited thereto, and the connection relationship of the first capacitor CST may change depending on the subpixel driving circuit.

A first planarization layer 118 and a second planarization layer 119 may be sequentially disposed on the subpixel driving circuit to planarize the surface. The first planarization layer 118 and the second planarization layer 119 may be organic films formed of, for example, polyimide or acrylic resin. The light-emitting element OLED may be formed on the second planarization layer 119.

The light-emitting element OLED may include an anode AND, a cathode CAT, and an emission layer EML disposed between the anode AND and the cathode CAT. In the case of a subpixel driving circuit that commonly uses a low level voltage applied to the cathode CAT, the anode AND is disposed as a separate electrode for each subpixel. On the other hand, in the case of a subpixel driving circuit that commonly uses a high level voltage, the cathode CAT may be disposed as a separate electrode for each subpixel.

The light-emitting element OLED may be electrically connected to a driving element through an intermediate electrode CNE disposed on the first planarization layer 118. For example, the anode AND of the light-emitting element OLED and the first source electrode SD1 of the polycrystalline thin film transistor TFT1 constituting the subpixel driving circuit may be connected to each other by the intermediate electrode CNE.

The anode AND may be connected to the intermediate electrode CNE exposed through a contact hole penetrating the second planarization layer 119. The intermediate electrode CNE may be connected to the first source electrode SD1 exposed through a contact hole penetrating the first planarization layer 118.

The intermediate electrode CNE may serve as a medium connecting the first source electrode SD1 and the anode AND. The intermediate electrode CNE may be formed of a conductive material such as copper (Cu), silver (Ag), molybdenum (Mo), or titanium (Ti).

The anode AND may be formed in a multilayer structure including a transparent conductive film and an opaque conductive film with high reflection efficiency. The transparent conductive film may be formed of a material having a relatively high work function value, such as indium-tin-oxide (ITO) or indium-zinc-oxide (IZO), and the opaque conductive film may be formed in a single-layer or multilayer structure including aluminum (Al), silver (Ag), copper (Cu), lead (Pb), molybdenum (Mo), titanium (Ti), or an alloy thereof. For example, the anode AND may be formed in a structure in which a transparent conductive film, an opaque conductive film, and a transparent conductive film are sequentially laminated, or a structure in which a transparent conductive film and an opaque conductive film are sequentially laminated. The emission layer EML is formed by sequentially or reversely laminating a hole-related layer, an organic emission layer, and an electron-related layer on the anode AND.

A bank layer BNK may be a subpixel defining film that exposes the anode AND of each subpixel. The bank layer BNK may be formed of an opaque material (e.g., black) to prevent optical interference between adjacent subpixels. In this case, the bank layer BNK may include a light-shielding material made of at least one of a color pigment, organic black, and carbon.

The cathode CAT may be formed on the upper surface and side surface of the emission layer EML while facing the anode AND with the emission layer EML interposed therebetween. The cathode CAT may be formed to cover the entire active area AA. When applied to a top-emitting organic light-emitting display device, the cathode CAT may be formed of a transparent conductive film such as indium-tin-oxide (ITO) or indium-zinc-oxide (IZO).

An encapsulation layer 120 that suppresses moisture penetration may be additionally disposed on the cathode CAT. The encapsulation layer 120 may block moisture or oxygen from penetrating into the emission layer EML that is vulnerable to moisture or oxygen from the outside. To this end, the encapsulation layer 120 may include at least one inorganic encapsulation layer and at least one organic encapsulation layer, but the present disclosure is not limited thereto. The encapsulation layer 120 may include a first encapsulation layer 121, a second encapsulation layer 122, and a third encapsulation layer 123 that are sequentially laminated.

The first encapsulation layer 121 and the third encapsulation layer 123 may be formed of an inorganic insulating material capable of low-temperature deposition, such as silicon nitride (SiNx), silicon oxide (SiOx), silicon oxynitride (SiON), or aluminum oxide (Al₂O₃). Since the first encapsulation layer 121 and the third encapsulation layer 123 are deposited in a low-temperature environment, the emission layer EML, which is vulnerable to high temperatures, can be prevented from being damaged during the deposition process of the first encapsulation layer 121 and the third encapsulation layer 123.

The second encapsulation layer 122 serves as a buffer to relieve stress between layers due to bending of the display device 10 and can flatten steps between layers. The second encapsulation layer 122 may be formed on the substrate 111 on which the first encapsulation layer 121 is formed, using a non-photosensitive organic insulating material such as an acrylic resin, an epoxy resin, a phenolic resin, a polyamide resin, a polyimide resin, and polyethylene or silicon oxycarbon (SiOC), or a photosensitive organic insulating material such as photoreactive acrylic, but the present disclosure is not limited thereto.

When the second encapsulation layer 122 is formed using an inkjet method, a dam DAM may be formed to prevent the second encapsulation layer 122 in a liquid form from spreading to the edge of the substrate 111. The dam DAM may be disposed closer to the edge of the substrate 111 than the second encapsulation layer 122. According to the dam DAM, the second encapsulation layer 122 can be prevented from spreading to a pad area where a conductive pad PAD (which is shown by the reference signs 158a, 158b, 158c and 158d) is disposed at the outermost edge of the substrate 111.

The dam DAM is designed to prevent spreading of the second encapsulation layer 122, but if the second encapsulation layer 122 is formed to exceed the height of the dam DAM during the process, the second encapsulation layer 122, which is an organic layer, can be exposed to the outside, and thus moisture, etc., can easily penetrate into the light-emitting element. Therefore, to prevent this, at least ten dams DAM may be formed.

The dam DAM may be disposed on the second interlayer insulating layer 117 of the non-active area NA. The dam DAM may be formed simultaneously with the first planarization layer 118 and the second planarization layer 119. A lower layer of the dam DAM may be formed simultaneously with formation of the first planarization layer 118, and an upper layer of the dam DAM may be formed simultaneously with formation of the second planarization layer 119, such that the dam DAM can be formed in a laminated structure. Accordingly, the dam DAM may be formed of the same materials as the first planarization layer 118 and the second planarization layer 119, but the present disclosure is not limited thereto.

The dam DAM may be formed to overlap the low-level voltage line EVSS. For example, the low-level voltage line EVSS may be located below the area where the dam DAM is located in the non-active area NA. The low-level voltage line EVSS may be disposed outside the gate driver 300 and may surround the active area AA. For example, the low-level voltage line EVSS may be made of the same material as the first gate electrode GE1, but is not limited thereto and may be made of the same material as the second electrode CST2 or the first source and drain electrodes SD1 and SD2. The low-level voltage line EVSS may be electrically connected to the cathode CAT to apply the low-level voltage EVSS to a plurality of subpixels included in the active area AA.

A touch layer may be disposed on the encapsulation layer 120. In the touch layer, a touch buffer film 151 may be positioned between a touch sensor metal layer including touch electrode connection lines 152 and 154 and touch electrodes 155 and 156 and the cathode CAT of the light-emitting element OLED. The touch buffer film 151 can block chemicals (developing solution or etching solution, etc.) used in the manufacturing process of the touch sensor metal layer disposed on the touch buffer film 151 or moisture from the outside from penetrating into the emission layer EML containing an organic material. Accordingly, the touch buffer film 151 can prevent damage to the emission layer EML that is vulnerable to chemicals or moisture.

The touch buffer film 151 may be formed of an organic insulating material that can be formed at a low temperature (e.g., 100° C. or lower) to prevent damage to the emission layer EML containing an organic material vulnerable to high temperatures and has a low dielectric constant of 1 to 3. For example, the touch buffer film 151 may be formed of an acrylic series, an epoxy series, or a siloxane series material. The touch buffer film 151 having a planarization performance due to an organic insulating material can prevent damage to the encapsulation layer 120 due to bending of the device and breakage of the touch sensor metal formed on the touch buffer film 151.

According to the mutual-capacitance-based touch sensor structure, the touch electrodes 155 and 156 may be disposed on the touch buffer film 151 and may be disposed to cross each other. The touch electrode connection lines 152 and 154 can electrically connect the touch electrodes 155 and 156. The touch electrode connection lines 152 and 154 and the touch electrodes 155 and 156 may be positioned in different layers with a touch insulating film 153 interposed therebetween. Optionally, the touch electrode connection lines 152 and 154 may be disposed to overlap the bank layer BNK, thereby preventing the aperture ratio from being reduced.

The touch electrodes 155 and 156 may be electrically connected to a touch driving circuit (not shown) via a touch pad PAD through a part of the touch electrode connection line 152 that passes through the upper and side surfaces of the encapsulation layer 120 and the upper and side surfaces of the dam DAM. The part of the touch electrode connection line 152 may receive a touch driving signal from the touch driving circuit and transmit the same to the touch electrodes 155 and 156, and may also transmit a touch sensing signal from the touch electrodes 155 and 156 to the touch driving circuit.

A touch passivation film 157 may be disposed on the touch electrodes 155 and 156. Although the touch passivation film 157 is illustrated as being disposed only on the touch electrodes 155 and 156, the present disclosure is not limited thereto, and the touch passivation film 157 may extend to the front or back of the dam DAM and may also be disposed on the touch electrode connection line 152. A color filter (not illustrated) may be disposed on the encapsulation layer 120, and the color filter may be located on the touch layer or between the encapsulation layer 120 and the touch layer.

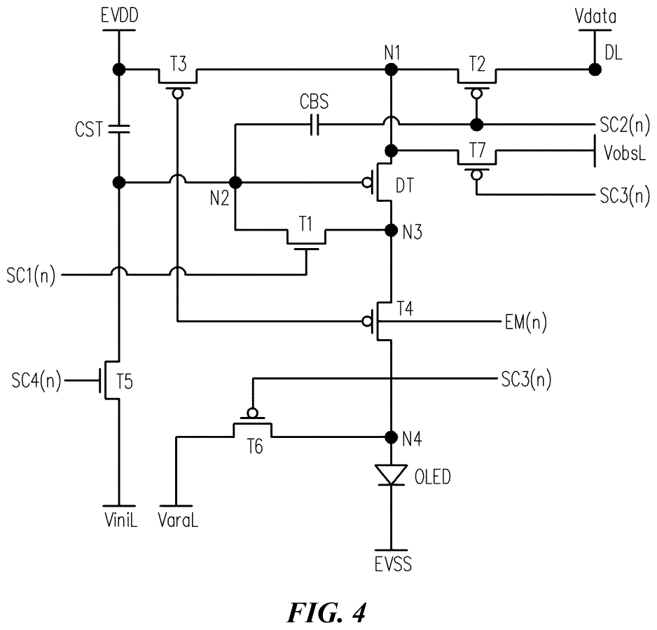

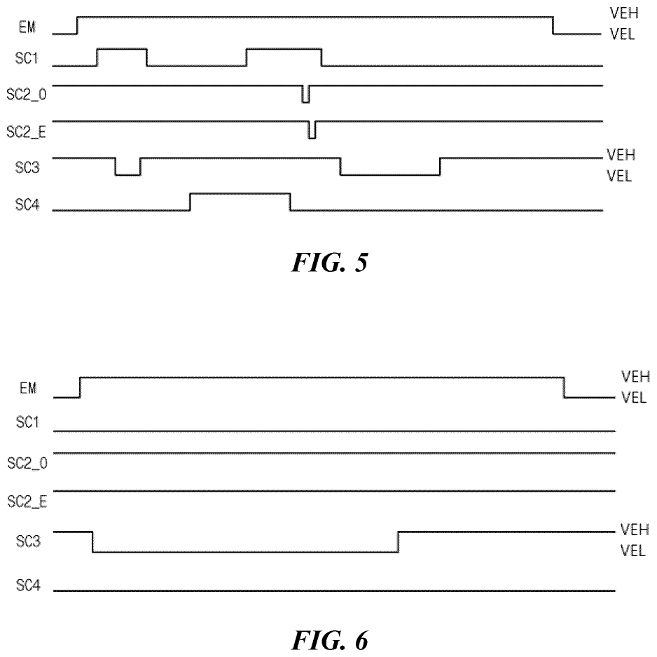

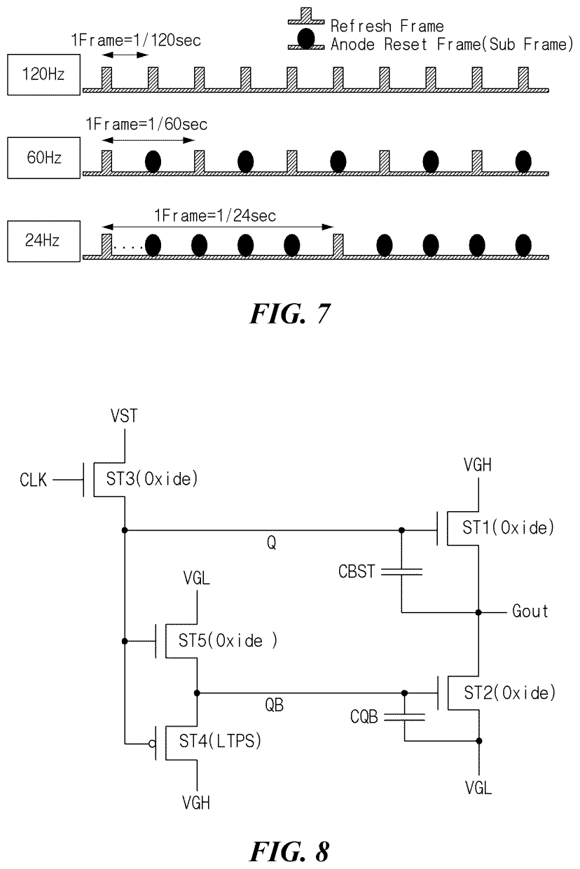

FIG. 4 is a diagram showing a circuit configuration of a subpixel according to the present disclosure. FIG. 5 and FIG. 6 are diagrams showing driving waveforms of a display panel implemented based on the subpixel of FIG. 4 according to the present disclosure. FIG. 7 is a diagram for describing driving characteristics of the display panel implemented based on the subpixel of FIG. 4.

As illustrated in FIG. 4, the subpixel P may include a first transistor T1, a second transistor T2, a third transistor T3, a fourth transistor T4, a fifth transistor T5, a sixth transistor T6, a seventh transistor T7, a driving transistor DT, a first capacitor CST, a second capacitor CBS, and a light-emitting element OLED. In FIG. 4, the first transistor T1 and the fifth transistor T5 are implemented as n-type oxide semiconductor-based transistors, and the second transistor T2, the third transistor T3, the fourth transistor T4, the sixth transistor T6, the seventh transistor T7, and the driving transistor DT are implemented as p-type polycrystalline semiconductor-based transistors, but the embodiment is not limited thereto.

The first transistor T1 may have a gate electrode connected to a first scan line SC1(n), a first electrode connected to a second node N2, and a second electrode connected to a third node N3. The first transistor T1 may be turned on in response to a first scan signal applied through the first scan line SC1(n). When the first transistor T1 is turned on, the threshold voltage of the driving transistor DT can be sampled.

The second transistor T2 may have a gate electrode connected to a second scan line SC2(n), a first electrode connected to a data line (DL), and a second electrode connected to a first node (N1). The second transistor T2 may be turned on in response to a second scan signal applied through the second scan line SC2(n). When the second transistor T2 is turned on, a data voltage Vdata applied through the data line DL can be transmitted to the first node N1.

The third transistor T3 may have a gate electrode connected to an emission control signal line EM(n), a first electrode connected to a high-level voltage line EVDD, and a second electrode connected to the first node N1. The third transistor T3 may be turned on in response to an emission control signal applied through the emission control signal line EM(n). When the third transistor T3 is turned on, the high-level voltage applied through the high-level voltage line EVDD can be transmitted to the first node N1.

The fourth transistor T4 may have a gate electrode connected to the emission control signal line EM(n), a first electrode connected to the third node N3, and a second electrode connected to the anode of the light emitting element OLED. The fourth transistor T4 may be turned on in response to the emission control signal applied through the emission control signal line EM(n). When the fourth transistor T4 is turned on, a driving current generated from the driving transistor DT can be transmitted to the light-emitting element OLED. When the fourth transistor T4 is turned on, the light-emitting element OLED can emit light based on the driving current generated from the driving transistor DT.

The fifth transistor T5 may have a gate electrode connected to a fourth scan line SC4(n), a first electrode connected to a first initialization voltage line ViniL, and a second electrode connected to the second node N2. The fifth transistor T5 may be turned on in response to a fourth scan signal applied through the fourth scan line SC4(n). When the fifth transistor T5 is turned on, a first initialization voltage applied through the first initialization voltage line ViniL can be transmitted to the second node N2. When the fifth transistor T5 is turned on, residual charge is present in the gate electrode of the driving transistor DT connected to the second node N2, a second electrode of the first capacitor CST, and a second electrode of the second capacitor CBS can be initialized.

The sixth transistor T6 may have a gate electrode connected to a third scan line SC3(n), a first electrode connected to a second initialization voltage line VaraL, and a second electrode connected to the anode of the light-emitting element OLED. The sixth transistor T6 may be turned on in response to a third scan signal applied through the third scan line SC3(n). When the sixth transistor T6 is turned on, a second initialization voltage applied through the second initialization voltage line VaraL can be transmitted to the anode of the light-emitting element OLED. When the sixth transistor T6 is turned on, residual charge present in the anode of the light-emitting element OLED can be initialized.

The seventh transistor T7 may have a gate electrode connected to the third scan line SC3(n), a first electrode connected to a bias voltage line VobsL, and a second electrode connected to the first node N1. The seventh transistor T7 may be turned on in response to the third scan signal applied through the third scan line SC3(n). When the seventh transistor T7 is turned on, a bias voltage applied through the bias voltage line VobsL can be transmitted to the first node N1. When the seventh transistor T7 is turned on, the driving transistor DT connected to the first node N1 can maintain a stronger saturation state by the bias voltage. Accordingly, a phenomenon in which a time for charging a voltage applied to the anode of the light-emitting element OLED during an emission period is reduced or delayed can be improved.

For example, as the level of the bias voltage Vobs increases, the voltage of the third node N3, which is the drain electrode of the driving transistor DT, can increase, and the gate-source voltage or the drain-source voltage of the driving transistor DT can decrease. Therefore, in some implementations, the level of the bias voltage Vobs is at least higher than the level of the data voltage Vdata. Under such a condition, the magnitude of the drain-source current Id passing through the driving transistor DT can be reduced, and the stress of the driving transistor DT can be reduced, and thus charging delay at the third node N3 can be eliminated. In other words, if an on-bias stress operation is performed before sampling the threshold voltage of the driving transistor DT, the hysteresis of the driving transistor DT can be alleviated.

The driving transistor DT may have a gate electrode connected to the second node N2, a first electrode connected to the first node N1, and a second electrode connected to the third node N3. The driving transistor DT may operate based on the data voltage Vdata stored in the first capacitor CST and may generate a driving current.

The first capacitor CST may have a first electrode connected to the high-level voltage line EVDD and the second electrode connected to the second node N2. The first capacitor CST may store the data voltage Vdata for a certain period of time and then transfer the same to the gate electrode of the driving transistor DT.

The second capacitor CBS may have a first electrode connected to the gate electrode of the second transistor T2 and the second scan line SC2(n), and the second electrode connected to the second node N2. The second capacitor CBS may serve to compensate for a voltage change at the second node N2 (e.g., perform voltage boosting for voltage reduction compensation) based on the second scan signal applied through the second scan line SC2(n).

The light-emitting element OLED may have the anode connected to the second electrode of the fourth transistor T4 and the cathode connected to the low-level voltage line EVSS. The light-emitting element OLED may emit light in response to the driving current transmitted through the turned-on fourth transistor T4.

The display panel implemented based on the subpixel P of FIG. 4 may be driven in a first driving mode based on the driving waveforms illustrated in FIG. 5, and may be driven in a second driving mode based on the driving waveforms illustrated in FIG. 6. The first driving mode may be included in a programming frame for high-speed driving of the display panel, and the second driving mode may be included in an anode reset frame for low-speed driving of the display panel.

As illustrated in FIG. 5 and FIG. 6, the first scan signal SC1, a second odd scan signal SC2_O, a second even scan signal SC2_E, the third scan signal SC3, and the fourth scan signal SC4 may be generated based on a gate high voltage VGH and a gate low voltage VGL, and the pulse shapes thereof may vary depending on the driving mode. On the other hand, the emission control signal EM may be generated based on a gate on voltage VEL and a gate off voltage VEH, and the pulse shape thereof may not vary depending on the driving mode.

However, the driving waveforms of FIG. 5 and FIG. 6 are merely examples and the present disclosure is not limited thereto.

In addition, the display panel implemented based on the subpixel of FIG. 4 should be interpreted as an example corresponding to one type of subpixel P that can be driven based on the gate driver which will be described below.

As illustrated in FIG. 1 and FIG. 7, the display panel 100 may operate in a variable refresh rate (VRR) mode based on the driving waveforms described above. The VRR mode is a driving method that can reduce power consumption by driving the display panel at a constant driving frequency and then increasing or decreasing the refresh rate to update the data voltage Vdata according to a high-speed driving or low-speed driving condition. For example, the display panel 100 can vary the driving speed, such as driving 1 frame at 120 Hz (1 frame= 1/120 sec), driving 1 frame at 60 Hz (1 frame= 1/60 sec), or driving 1 frame at 24 Hz (1 frame= 1/24 sec).

In a high-speed driving condition such as 120 Hz, a refresh frame in which the data voltage Vdata can be refreshed (an image can be refreshed) may be included in each frame. On the other hand, in a low-speed driving condition such as 60 Hz or 24 Hz, the data voltage Vdata can be refreshed for every N frames (N being an integer equal to or greater than 1) and an anode reset frame can be included between the refresh frames.

The anode reset frame belongs to a subframe and can operate the device such that normal image expression of the display panel 100 is possible even in the frame. However, the anode reset frame can be performed under the low-speed driving condition. Therefore, the anode reset frame is a frame in which there is little movement of an image or a still image is displayed, and thus only output of a scan signal can be performed in a state in which output of the data voltage Vdata is stopped, but the present disclosure is not limited thereto.

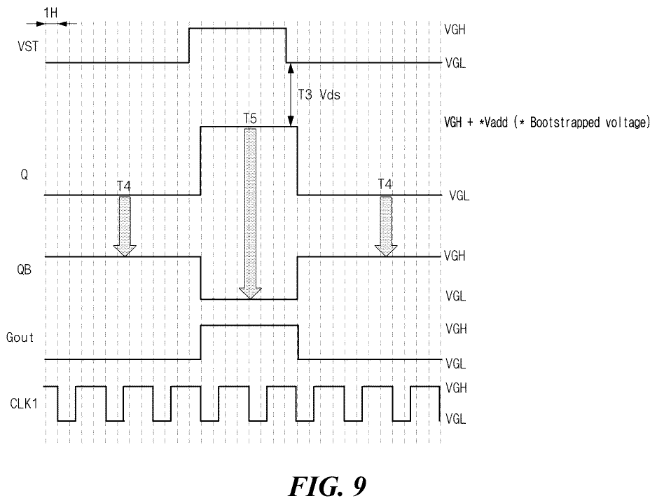

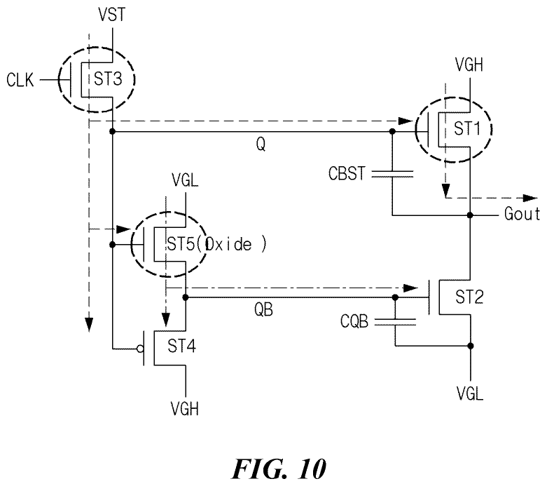

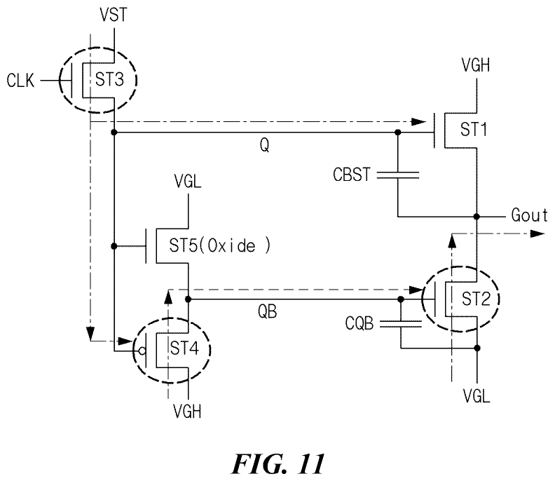

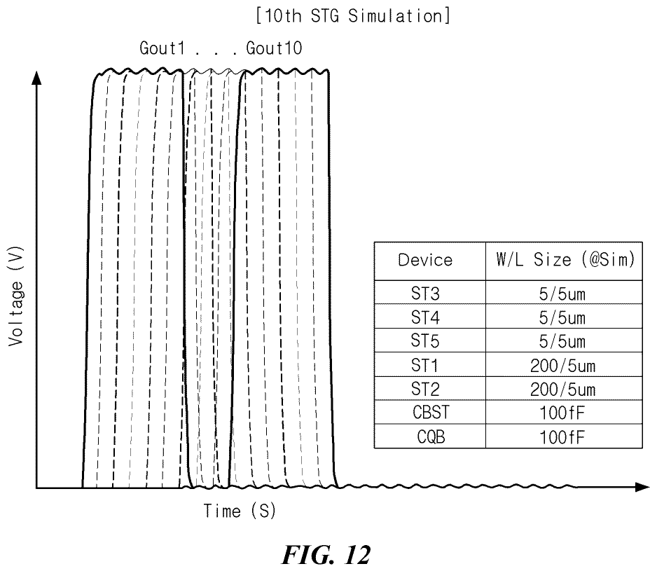

FIG. 8 is a circuit configuration diagram of a shift register according to a first embodiment, FIG. 9 is a diagram showing driving waveforms of the shift register illustrated in FIG. 8, FIG. 10 and FIG. 11 show operation states of the shift register according to the driving waveforms illustrated in FIG. 9, and FIG. 12 shows output states of the shift register according to the first embodiment.

As illustrated in FIG. 8, an Nth shift register (N being an arbitrary number) according to the first embodiment may include a first scan transistor ST1, a second scan transistor ST2, a third scan transistor ST3, a fourth scan transistor ST4, a fifth scan transistor ST5, a first scan capacitor CBST, and a second scan capacitor CQB.

The first scan transistor ST1, the second scan transistor ST2, the third scan transistor ST3, and the fifth scan transistor ST5 may be n-type transistors implemented based on an oxide semiconductor. The fourth scan transistor ST4 may be a p-type transistor implemented based on a low-temperature polysilicon (LTPS) semiconductor. The n-type transistor has low leakage characteristics, and the p-type transistor has high mobility characteristics. Therefore, the Nth shift register according to the first embodiment may have low leakage characteristics and high mobility characteristics.

The first scan transistor ST1 may have a gate electrode connected to a Q node Q, a first electrode connected to a gate high voltage line (or a first voltage line) VGH through which a gate high voltage is transmitted, and a second electrode connected to an output terminal (Gout). The first scan transistor ST1 may be turned on based on the voltage of the Q node Q and may output a first-level scan signal provided based on the gate high voltage.

The first scan capacitor CBST may have a first electrode connected to the Q node Q and a second electrode connected to the output terminal Gout. The first scan capacitor CBST may perform bootstrapping such that the voltage of the Q node Q increases.

The second scan transistor ST2 may have a gate electrode connected to a QB node QB, a first electrode connected to a gate low voltage line (or a second voltage line) VGL through which a gate low voltage is transmitted, and a second electrode connected to the output terminal Gout. The second scan transistor ST2 may be turned on based on the voltage of the QB node QB and may output a second-level scan signal provided based on the gate low voltage.

The second scan capacitor CQB may have a first electrode connected to the QB node QB and a second electrode connected to the gate low voltage line VGL. The second scan capacitor CQB may keep the voltage of the QB node QB constant.

The third scan transistor ST3 may have a gate electrode connected to a clock signal line CLK through which a clock signal is transmitted, a first electrode connected to a start signal line VST (or an output terminal of an (N-1)th stage) through which a start signal is transmitted, and a second electrode connected to the Q node Q. The third scan transistor ST3 may be turned on in response to the clock signal and transmit the start signal to the Q node Q. Since the third scan transistor ST3 is implemented based on an oxide semiconductor, the third scan transistor ST3 can prevent a high voltage (high Vds) from leaking through the drain and the source.

The fourth scan transistor ST4 may have a gate electrode connected to the Q node Q, a first electrode connected to the gate high voltage line VGH, and a second electrode connected to the QB node QB. The fourth scan transistor ST4 may be turned on based on the voltage of the Q node Q and may transmit the gate high voltage to the QB node QB.

The fifth scan transistor ST5 may have a gate electrode connected to the Q node Q, a first electrode connected to the gate low voltage line VGL through which the gate low voltage is transmitted, and a second electrode connected to the QB node QB. The fifth scan transistor ST5 may be turned on based on the voltage of the Q node Q and may transmit the gate low voltage to the QB node QB. The fourth scan transistor ST4 and the fifth scan transistor ST5 may be implemented as CMOS transistors that perform opposite operations depending on the voltage of the Q node Q.

As illustrated in FIG. 9, the Nth shift register according to the first embodiment can output a scan signal Gout by performing charging and discharging with the voltage of the Q node Q and the voltage of the QB node QB opposite to each other on the basis of the start signal VST and a first clock signal CLK1. This will be described in more detail as follows. For reference, the waveforms of FIG. 9 are illustrated in units of 1 horizontal time 1H based on the vertical dotted line, which should be interpreted as an example. In addition, an example in which the first clock signal CLK1 and the start signal VST have pulses of a high voltage and a low voltage based on the gate high voltage VGH and the gate low voltage VGL is illustrated, which should also be interpreted as an example.

As illustrated in FIG. 9 and FIG. 10, the third scan transistor ST3 may be repeatedly turned on and off based on the pulse-type first clock signal CLK1 applied through the clock signal line CLK. The third scan transistor ST3 may transmit the start signal VST generated as a gate high voltage VGH to the Q node Q upon being turned on.

The Q node Q may be charged based on the gate high voltage VGH transmitted through the third scan transistor ST3. The Q node Q before being charged (or the discharged Q node) may have a gate low voltage (VGL) level, and the charged Q node Q may have a gate high voltage (VGH) level.

The voltage of the Q node Q may rise to “VGH+*Vadd (*bootstrapped voltage)” by the sum of the gate high voltage VGH and a bootstrapped voltage of the first scan capacitor CBST. Here, *Vadd (*bootstrapped voltage) means that the bootstrapped voltage by the first scan capacitor CBST is added to the gate high voltage VGH.

Accordingly, the fourth scan transistor ST4 can be subjected to voltage change at the level of the gate low voltage VGL applied to the Q node Q and the gate high voltage VGH applied to the QB node QB. On the other hand, the fifth scan transistor ST5 can be subjected to voltage change at the level of the additional increase VGH+*Vadd of the gate high voltage applied to the Q node Q and the gate low voltage VGL applied to the QB node QB. At this time, the drain-source voltage T3 Vds of the third scan transistor ST3 may be at the level of the additional increase VGH+*Vadd of the gate high voltage applied to the Q node Q and the gate low voltage VGL of the start signal.

Meanwhile, the first scan transistor ST1 and the fifth scan transistor ST5 may be turned on based on the high voltage charged at the Q node Q. At this time, when the Q node Q is charged with the high voltage, the QB node QB may be in a discharged state based on the gate low voltage VGL transmitted through the turned-on fifth scan transistor ST5. Accordingly, the second scan transistor ST2 may be in a turned-off state. When the Q node Q is charged with the high voltage, the turned-on first scan transistor ST1 can output a first-level scan signal based on the gate high voltage VGH through the output terminal Gout.

As illustrated in FIG. 9 and FIG. 11, the third scan transistor ST3 may be repeatedly turned on and off based on the pulse-type first clock signal CLK1 applied through the clock signal line CLK. The third scan transistor ST3 can transmit the start signal VST switched to the gate low voltage VGL to the Q node Q upon being turned on.

The Q node Q may be discharged based on the gate low voltage VGL transmitted through the third scan transistor ST3. Accordingly, the first scan transistor ST1 and the fifth scan transistor ST5 can be turned off.

The voltage of the Q node Q is switched to the gate low voltage VGL and thus the Q node is discharged, and the fifth scan transistor ST5 is turned off, whereas the fourth scan transistor ST4 is turned on.

The QB node QB may be charged based on the gate high voltage VGH as the fourth scan transistor ST4 is turned on. The second scan transistor ST2 may be turned on based on the high voltage charged at the QB node QB. When the QB node QB is charged with the high voltage, the turned-on second scan transistor ST2 can output a second-level scan signal based on the gate low voltage VGL through the output terminal Gout.

The shift register according to the first embodiment may be configured in a plurality of stages. The shift register according to the first embodiment was implemented with 10 stages and simulations were performed. As a result, as shown in FIG. 12, it was confirmed that normal output can be performed in the form of first to tenth scan signals Gout1 to Gout10.

The shift register according to the first embodiment may be included in stages each constituting at least one of the emission control signal driver 310, the first scan driver 321, the third scan driver 323, and the fourth scan driver 324 in FIG. 2.

Meanwhile, the device specifications (W/L size) of the first scan transistor ST1 to the fifth scan transistor ST5, the first scan capacitor CBST, and the second scan capacitor CQB for deriving the simulation result of FIG. 12 are merely examples and the present disclosure is not limited thereto.

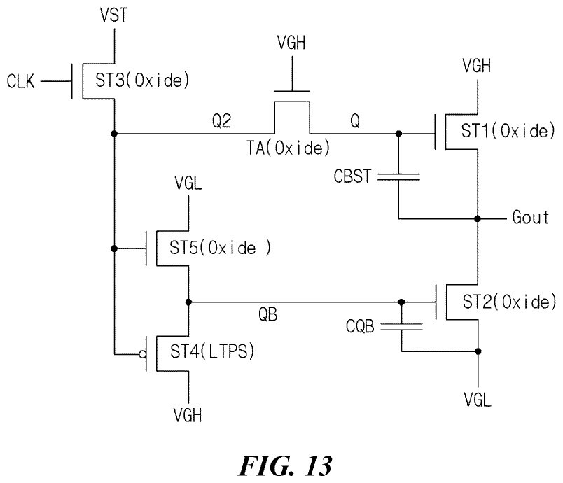

FIG. 13 is a circuit configuration diagram of a shift register according to a second embodiment.

As illustrated in FIG. 13, an Nth shift register (N being an arbitrary number) according to the second embodiment may include a first scan transistor ST1, a second scan transistor ST2, a third scan transistor ST3, a fourth scan transistor ST4, a fifth scan transistor ST5, a compensation transistor TA, a first scan capacitor CBST, and a second scan capacitor CQB.

The first scan transistor ST1, the second scan transistor ST2, the third scan transistor ST3, the fifth scan transistor ST5, and the compensation transistor TA may be n-type transistors implemented based on an oxide semiconductor. The fourth scan transistor ST4 may be a p-type transistor implemented based on low-temperature polysilicon (LTPS) semiconductor.

Since the connection relationship of the first scan transistor ST1, the second scan transistor ST2, the first scan capacitor CBST, and the second scan capacitor CQB is the same as in FIG. 8, refer to the first embodiment.

The third scan transistor ST3 may have a gate electrode connected to a clock signal line CLK through which a clock signal is transmitted, a first electrode connected to a start signal line VST (or an output terminal of an (N-1)th stage) through which a start signal is transmitted, and a second electrode connected to a Q2 node Q2. The third scan transistor ST3 may be turned on in response to the clock signal and transmit the start signal to the Q2 node Q2.

The fourth scan transistor ST4 may have a gate electrode connected to the Q2 node Q2, a first electrode connected to a gate high voltage line VGH, and a second electrode connected to a QB node QB. The fourth scan transistor ST4 may be turned on based on the voltage of the Q2 node Q2 and transmit the gate high voltage to the QB node QB.

The fifth scan transistor ST5 may have a gate electrode connected to the Q2 node Q2, a first electrode connected to a gate low voltage line VGL through which a gate low voltage is transmitted, and a second electrode connected to the QB node QB. The fifth scan transistor ST5 may be turned on based on the voltage of the Q2 node Q2 and transmit the gate low voltage to the QB node QB. The fourth scan transistor ST4 and the fifth scan transistor ST5 may be implemented as CMOS transistors that perform opposite operations depending on the voltage of the Q2 node Q2.

The compensation transistor TA may have a gate electrode connected to the gate high voltage line VGH, a first electrode connected to the Q2 node Q2, and a second electrode connected to the Q node Q. The compensation transistor TA may electrically stabilize the Q2 node Q2 and the Q node Q and protect the transistors T4 and T5 connected to the Q2 node Q2 from breakdown. In addition, since the third scan transistor ST3 is implemented based on an oxide semiconductor, it can prevent a high voltage (High Vds) from leaking through the drain and the source. For this reason, the compensation transistor TA according to the second embodiment may be omitted. However, the compensation transistor TA may be used to electrically stabilize the nodes Q and Q2.

The Nth shift register according to the second embodiment is similar to the first embodiment except that the compensation transistor TA, and can operate in a similar manner to the first embodiment. Therefore, refer to the first embodiment for the operation of the Nth shift register according to the second embodiment.

The shift register according to the second embodiment may be included in stages each constituting at least one of the emission control signal driver 310, the first scan driver 321, the third scan driver 323, and the fourth scan driver 324 in FIG. 2.

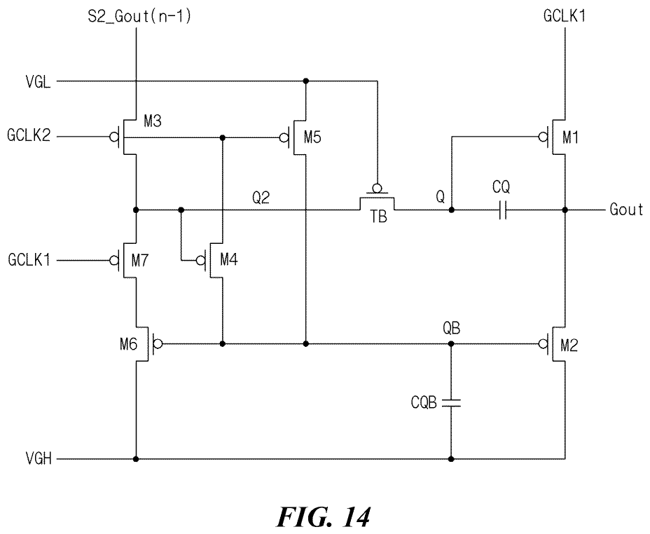

FIG. 14 is a circuit configuration diagram of a shift register according to a third embodiment.

As illustrated in FIG. 14, an Nth shift register (N being an arbitrary number) according to the third embodiment may include an eleventh transistor M1, a twelfth transistor M2, a thirteenth transistor M3, a fourteenth transistor M4, a fifteenth transistor M5, a sixteenth transistor M6, a seventeenth transistor M7, a second compensation transistor TB, a third capacitor CQ, and a fourth capacitor CQB.

The eleventh transistor M1, the twelfth transistor M2, the thirteenth transistor M3, the fourteenth transistor M4, the fifteenth transistor M5, the sixteenth transistor M6, the seventeenth transistor M7, and the second compensation transistor TB may be p-type transistors implemented based on an LTPS semiconductor.

The eleventh transistor M1 may have a gate electrode connected to a Q node Q, a first electrode connected to a first gate clock signal line GCLK1 through which a first gate clock signal is transmitted, and a second electrode connected to an output terminal Gout. The eleventh transistor M1 may be turned on based on the voltage of the Q node Q to output a second-level scan signal based on the first gate clock signal.

The third capacitor CQ may have a first electrode connected to the Q node Q and a second electrode connected to the output terminal Gout. The third capacitor CQ may perform bootstrapping such that the voltage of the Q node Q increases.

The twelfth transistor M2 may have a gate electrode connected to a QB node QB, a first electrode connected to a gate high voltage line VGH through which a gate high voltage is transmitted, and a second electrode connected to the output terminal Gout. The twelfth transistor M2 may be turned on based on the voltage of the QB node QB to output a first-level scan signal based on the gate high voltage.

The thirteenth transistor M3 may have a gate electrode connected to a second gate clock signal line GCLK2 through which a second gate clock signal is transmitted, a first electrode connected to an output terminal S2_Gout(n-1) of an (N-1)th stage (or a start signal line), and a second electrode connected to a Q2 node Q2. The thirteenth transistor M3 may be turned on in response to the second gate clock signal and transmit the output signal (or start signal) of the (N-1)th stage to the Q2 node Q2.

The fourteenth transistor M4 may have a gate electrode connected to the Q2 node Q2, a first electrode connected to the second gate clock signal line GCLK2, and a second electrode connected to the QB node QB. The fourteenth transistor M4 may be turned on based on the voltage of the Q2 node Q2 and transmit the second gate clock signal to the QB node QB.

The fifteenth transistor M5 may have a gate electrode connected to the second gate clock signal line GCLK2, a first electrode connected to a gate low voltage line VGL through which a gate low voltage is transmitted, and a second electrode connected to the QB node QB. The fifteenth transistor M5 may be turned on in response to the second gate clock signal to transmit the gate low voltage to the QB node QB.

The sixteenth transistor M6 may have a gate electrode connected to the QB node QB, a first electrode connected to the gate high voltage line VGH, and a second electrode connected to a second electrode of the seventeenth transistor M7. The sixteenth transistor M6 may be turned on based on the voltage of the QB node QB to transmit the gate high voltage to the second electrode of the seventeenth transistor M7.

The seventeenth transistor M7 may have a gate electrode connected to the first gate clock signal line GCLK1, a first electrode connected to the Q2 node Q2, and a second electrode connected to the second electrode of the sixteenth transistor M6. The seventeenth transistor M7 may be turned on in response to the first gate clock signal to transmit the gate high voltage applied from the sixteenth transistor M6 to the Q2 node Q2.

The second compensation transistor TB may have a gate electrode connected to the gate low voltage line VGL, a first electrode connected to the Q2 node Q2, and a second electrode connected to the Q node Q. The second compensation transistor TB may electrically stabilize the Q2 node Q2 and the Q node Q and protect the transistors M4 and M7 connected to the Q2 node Q2 from breakdown.

The shift register according to the third embodiment may be included in stages each constituting at least one of the odd-numbered second scan driver 322_O and the even-numbered second scan driver 322_E in FIG. 2. In other words, the shift register according to the third embodiment can generate a second scan signal applied to the gate electrode of the second transistor T2 in FIG. 4 for applying the data voltage. Therefore, the first gate clock signal and the second gate clock signal can be applied at the timing of generating and outputting the second scan signal.

Referring to the first to third embodiments, the gate driver according to the present disclosure may include a first type shift register including an oxide semiconductor and a low-temperature polysilicon semiconductor and a second type shift register including a low-temperature polysilicon semiconductor. In addition, referring to the first and second embodiments, the gate driver according to the present disclosure can reduce the number of transistors for controlling the QB node based on CMOS transistors. In addition, referring to the first and second embodiments, the gate driver according to the present disclosure can solve a problem due to current leakage according to a shift register including an oxide semiconductor.

The present disclosure has the effect of providing a gate driver capable of reducing the number of transistors for controlling a QB node based on CMOS transistors and solving a problem due to current leakage according to a shift register including an oxide semiconductor, and a display device including the same. In addition, the present disclosure has the effect of providing a gate driver capable of improving operation stability and operational reliability based on a shift register including at least one of an oxide semiconductor or a low-temperature polysilicon semiconductor, and a display device including the same.

It will be apparent to those skilled in the art that various modifications and variations can be made in the present disclosure without departing from the spirit or scope of the present disclosure. Thus, it is intended that the present disclosure cover the modifications and variations of the present disclosure including the appended claims and their equivalents.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel configured to display an image; and
a gate driver including a shift register configured to generate signals for controlling transistors included in the display panel,
wherein the shift register comprises:
a first scan transistor configured to be turned on based on a voltage of a Q node to output a first-level signal through an output terminal;
a second scan transistor configured to be turned on based on a voltage of a QB node to output a second-level signal through the output terminal;
a third scan transistor configured to be turned on in response to a clock signal applied through a clock signal line to transmit a start signal applied through a start signal line to the Q node; and
CMOS transistors configured to control the QB node based on the voltage of the Q node.

2. The display device of claim 1, wherein the CMOS transistors include a fourth scan transistor having a gate electrode connected to the Q node, a first electrode connected to a first voltage line through which a first voltage is transmitted, and a second electrode connected to the QB node, and a fifth scan transistor having a gate electrode connected to the Q node, a first electrode connected to a second voltage line through which a second voltage is transmitted, and a second electrode connected to the QB node.

3. The display device of claim 2, wherein the fourth scan transistor is a p-type transistor having a polysilicon semiconductor, and the fifth scan transistor is an n-type transistor having an oxide semiconductor.

4. The display device of claim 3, wherein the first scan transistor, the second scan transistor, and the third scan transistor are n-type transistors each having on an oxide semiconductor.

5. The display device of claim 1, further comprising:
a first scan capacitor having a first electrode connected to a gate electrode of the first scan transistor and a second electrode connected to the output terminal; and
a second scan capacitor having a first electrode connected to a gate electrode of the second scan transistor and a second electrode connected to a second voltage line.

6. The display device of claim 1, wherein the gate driver includes a scan driver configured to supply a scan signal to the display panel, and an emission control signal driver configured to supply an emission control signal to the display panel, and
the shift register is included in at least one of the scan driver and the emission control signal driver.

7. The display device of claim 1, wherein the gate driver comprises:
a first scan driver configured to supply a first scan signal to the display panel;
a second scan driver configured to supply a second scan signal to the display panel;
a third scan driver configured to supply a third scan signal to the display panel;
a fourth scan driver configured to supply a fourth scan signal to the display panel; and
an emission control signal driver configured to supply an emission control signal to the display panel,
wherein the shift register is included in at least one of the first scan driver, the third scan driver, the fourth scan driver, and the emission control signal driver.

8. A gate driving circuit comprising:
a first scan transistor configured to be turned on based on a voltage of a Q node to output a first-level signal through an output terminal;
a second scan transistor configured to be turned on based on a voltage of a QB node to output a second-level signal through the output terminal;
a third scan transistor configured to be turned on in response to a clock signal applied through a clock signal line to transmit a start signal applied through a start signal line to the Q node; and
CMOS transistors configured to control the QB node based on the voltage of the Q node.

9. The gate driving circuit of claim 8, wherein the CMOS transistors include a fourth scan transistor having a gate electrode connected to the Q node, a first electrode connected to a first voltage line through which a first voltage is transmitted, and a second electrode connected to the QB node, and a fifth scan transistor having a gate electrode connected to the Q node, a first electrode connected to a second voltage line through which a second voltage is transmitted, and a second electrode connected to the QB node.

10. The gate driving circuit of claim 9, wherein the first scan transistor, the second scan transistor, the third scan transistor, and the fifth scan transistor are n-type transistors each having an oxide semiconductor, and the fourth scan transistor is a p-type transistor having a polysilicon semiconductor.
